(19) United States
(12) Patent Application Publication
(10) Pub. No.: US 2025/0107212 A1
(43) Pub. Date: Mar. 27, 2025

(54) AIRGAP SPACER BETWEEN GATE ELECTRODE AND SOURCE OR DRAIN CONTACT

(71) Applicant: Intel Corporation, Santa Clara, CA (US)

(72) Inventors: Yang Zhang, Rio Rancho, NM (US); Guowei Xu, Portland, OR (US); Tao Chu, Portland, OR (US); Robin Chao, Portland, OR (US); Chiao-Ti Huang, Portland, OR (US); Feng Zhang, Hillsboro, OR (US); Ting-Hsiang Hung, Beaverton, OR (US); Chia-Ching Lin, Portland, OR (US); Anand Murthy, Portland, OR (US)

(73) Assignee: Intel Corporation, Santa Clara, CA (US)

(21) Appl. No.: 18/471,705

(22) Filed: Sep. 21, 2023

(51) Int. Cl. H01L 29/49; H01L 21/28; H01L 21/78; H01L 29/06; H01L 29/417; H01L 29/423; H01L 29/66; H01L 29/775

(52) U.S. Cl. CPC H10D 64/679; H01L 21/28123; H01L 21/7806; H10D 30/014; H10D 30/43; H10D 30/6729; H10D 30/6735; H10D 62/121; H10D 64/017

(57) ABSTRACT

Techniques are provided to form an integrated circuit having an airgap spacer between at least a transistor gate structure and an adjacent source or drain contact. In one such example, a FET (field effect transistor) includes a gate structure that extends around a fin or any number of nanowires (or nanoribbons or nanosheets, as the case may be) of semiconductor material. The semiconductor material may extend in a first direction between source and drain regions while the gate structure extends over the semiconductor material in a second direction. Airgaps are provided in the regions between the gate structures and the adjacent source/drain contacts. The airgaps have a low dielectric constant (e.g., around 1.0) to reduce the parasitic capacitance between the conductive structures.

### BACKGROUND

As integrated circuits continue to scale downward in size, a number of challenges arise. For instance, reducing the size of memory and logic cells within the interconnect structure is becoming increasingly more difficult, as is reducing device spacing at the device layer. As transistors are packed more densely, parasitic effects due to adjacent conductive structures become more prominent and can degrade transistor performance. Accordingly, there remain a number of non-trivial challenges with respect to forming such high-density semiconductor devices.

### BRIEF DESCRIPTION OF THE DRAWINGS

FIGS. 1A and 1B are different cross-sectional views of an integrated circuit that includes an airgap spacer between gate structures and source or drain contacts, in accordance with an embodiment of the present disclosure.

FIGS. 2A and 2B are cross-sectional views that illustrate one stage in an example process for forming an integrated circuit configured with an airgap spacer between gate structures and source or drain contacts, in accordance with an embodiment of the present disclosure.

FIGS. 3A and 3B are cross-sectional views that illustrate another stage in the example process for forming an integrated circuit configured with an airgap spacer between gate structures and source or drain contacts, in accordance with an embodiment of the present disclosure.

FIGS. 4A and 4B are cross-sectional views that illustrate another stage in the example process for forming an integrated circuit configured with an airgap spacer between gate structures and source or drain contacts, in accordance with an embodiment of the present disclosure.

FIGS. 5A and 5B are cross-sectional views that illustrate another stage in the example process for forming an integrated circuit configured with an airgap spacer between gate structures and source or drain contacts, in accordance with an embodiment of the present disclosure.

FIGS. 6A and 6B are cross-sectional views that illustrate another stage in the example process for forming an integrated circuit configured with an airgap spacer between gate structures and source or drain contacts, in accordance with an embodiment of the present disclosure.

FIGS. 7A and 7B are cross-sectional views that illustrate another stage in the example process for forming an integrated circuit configured with an airgap spacer between gate structures and source or drain contacts, in accordance with an embodiment of the present disclosure.

FIGS. 8A and 8B are cross-sectional views that illustrate another stage in the example process for forming an integrated circuit configured with an airgap spacer between gate structures and source or drain contacts, in accordance with an embodiment of the present disclosure.

FIGS. 9A and 9B are cross-sectional views that illustrate another stage in the example process for forming an integrated circuit configured with an airgap spacer between gate structures and source or drain contacts, in accordance with an embodiment of the present disclosure.

FIGS. 10A and 10B are cross-sectional views that illustrate another stage in the example process for forming an integrated circuit configured with an airgap spacer between gate structures and source or drain contacts, in accordance with an embodiment of the present disclosure.

FIGS. 11A and 11B are cross-sectional views that illustrate another stage in the example process for forming an integrated circuit configured with an airgap spacer between gate structures and source or drain contacts, in accordance with an embodiment of the present disclosure.

FIGS. 12A and 12B are cross-sectional views that illustrate another stage in the example process for forming an integrated circuit configured with an airgap spacer between gate structures and source or drain contacts, in accordance with an embodiment of the present disclosure.

FIGS. 13A and 13B are cross-sectional views that illustrate another stage in the example process for forming an integrated circuit configured with an airgap spacer between gate structures and source or drain contacts, in accordance with an embodiment of the present disclosure.

FIGS. 14A and 14B are cross-sectional views that illustrate another stage in the example process for forming an integrated circuit configured with an airgap spacer between gate structures and source or drain contacts, in accordance with an embodiment of the present disclosure.

FIGS. 15A and 15B are cross-sectional views that illustrate another stage in the example process for forming an integrated circuit configured with an airgap spacer between gate structures and source or drain contacts, in accordance with an embodiment of the present disclosure.

FIG. 16 illustrates a cross-sectional view of a chip package containing one or more semiconductor dies, in accordance with some embodiments of the present disclosure.

FIG. 17 is a flowchart of a fabrication process for an integrated circuit that includes an airgap spacer between gate structures and source or drain contacts, in accordance with an embodiment of the present disclosure.

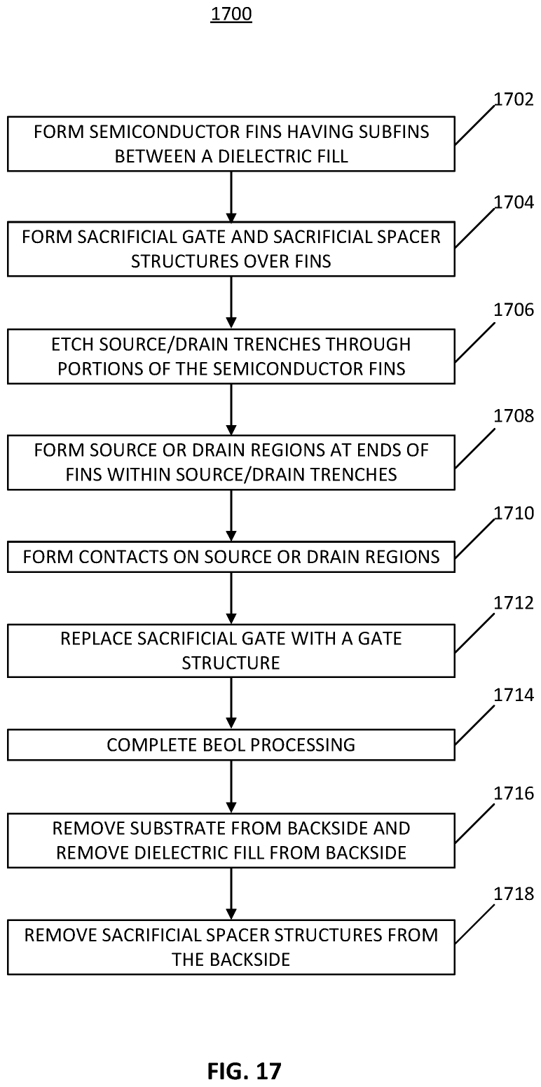

FIG. 18 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having an airgap spacer between at least a transistor gate structure and an adjacent source or drain contact. The techniques can be used in any number of integrated circuit applications and are particularly useful with respect to logic and memory cells, such as those cells that use finFETs or gate-all-around transistors (e.g., ribbonFETs and nanowire FETs) or forksheet transistors (e.g., nanosheet FETs). In one such example, a FET (field effect transistor) includes a gate structure having a gate electrode on a gate dielectric. The gate structure extends around a fin or any number of nanowires (or nanoribbons or nanosheets, as the case may be) of semiconductor material. The semiconductor material may extend in a first direction between source and drain regions while the gate structure extends over the semiconductor material in a second direction substantially orthogonal to the first direction. During the fabrication process, spacer structures separate the gate structure from an adjacent source/drain trench, which includes the source or drain regions and contacts over the source or drain regions. According to an embodiment, the spacer structures are replaced with airgaps to provide regions having a low dielectric constant (e.g., around 1.0) between the gate structure and one or more adjacent contacts to reduce the parasitic capacitance between the structures. In some other examples, the spacer structures may be replaced with a low-k dielectric material (e.g., a dielectric material having a dielectric constant of silicon dioxide or lower). In still other embodiments, the spacer structures are replaced by a combination of airgaps and dielectric material, to provide an overall low dielectric constant (e.g., between 1.0 and 3.4). Numerous variations and embodiments will be apparent in light of this disclosure.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. Various conductive elements must be separated from each other to provide a working circuit, yet their proximity can create parasitic capacitance that reduces switching speeds of transistors and degrades the overall performance. One example of such parasitic capacitance occurs between transistor gate structures and adjacent metallic contacts on source or drain regions. These conductive elements are separated from each other by a spacer structure. However, the spacer structure is often made with a robust high-k dielectric material (e.g., a material with a dielectric constant of 6.5 or greater, such as silicon nitride) to withstand the various fabrication processes that occur to form other transistor structures. The high dielectric constant of the spacer structure may yield a high parasitic capacitance between the gate structure and source or drain contact.

Thus, and in accordance with an embodiment of the present disclosure, techniques are provided herein to reduce parasitic capacitance between the gate structure and source or drain contact. In an example, the techniques include replacing the spacer structure between the gate structure and the source or drain contact with an airgap spacer and/or a relatively low dielectric constant material, to provide a separating region with a relatively low dielectric constant. In some examples, the airgap spacer provides a region having a dielectric constant of around 1.0 (all of spacer laterally between gate structure and contact is removed), while in other examples the airgap spacer includes some low-k dielectric material in combination with voids to provide a region having a dielectric constant between 1.0 and 3.4 (at least some of spacer laterally between gate structure and contact is removed). According to some embodiments, front-side processing of transistor structures proceeds using a sacrificial spacer structure material that is still robust enough to withstand the various fabrication procedures. In some examples, the spacer structures are formed using aluminum oxide. Once front side processing is completed, the substrate may be removed from the backside of the integrated circuit along with any shallow trench isolation (STI) dielectric to expose portions of the spacer structures from the backside. The spacer structures may then be selectively etched away using an isotropic etching technique, such as an ammonia-based gas etchant to remove the spacer structures and leave behind an airgap. The airgap may include an inert gas, such as argon, or may be substantially devoid of gaseous elements and at vacuum pressure. In some other embodiments, the airgap space may be filled or partially filled with a low-k dielectric material, such as a low-density flowable oxide (e.g., porous silicon dioxide).

According to an embodiment, an integrated circuit includes a semiconductor device having a semiconductor region extending in a first direction from a source or drain region and a gate structure extending in a second direction over the semiconductor region, a contact on a surface of the source or drain region, and an airgap between an upper portion of the gate structure and the contact. The contact may be, for example, on top and/or on one or more sidewalls of the source or drain region, and may extend into the source or drain region. In any such cases, the airgap has a lateral width along the first direction between the upper portion of the gate structure and the contact.

According to another embodiment, an electronic device includes a chip package having one or more dies. At least one of the one or more dies includes a semiconductor region extending in a first direction from a first source or drain region to a second source or drain region, a gate structure extending in a second direction over the semiconductor region with the second direction being different from the first direction, a contact on a surface of the source or drain region, and an airgap between an upper portion of the gate structure and the contact and between a remaining portion of the gate structure and the source or drain region. The airgap has a lateral width along the first direction between the upper portion of the gate structure and the contact and between the remaining portion of the gate structure and the source or drain region.

According to another embodiment, an integrated circuit includes a first semiconductor device having a first semiconductor region extending in a first direction from a first side of a source or drain region and a first gate structure extending in a second direction over the first semiconductor region, a second semiconductor device having a second semiconductor region extending in the first direction from a second side of the source or drain region opposite from the first side and a second gate structure extending in the second direction over the second semiconductor region, a contact on a surface of the source or drain region, a first airgap between an upper portion of the first gate structure and the contact, and a second airgap between an upper portion of the second gate structure and the contact. The first airgap has a first lateral width along the first direction and the second airgap has a second lateral width along the first direction. The second lateral width is substantially the same as the first lateral width. Dimensions may be considered to be substantially the same if they are within 1 nm or within 2 nm of each other.

According to an embodiment, a method of forming an integrated circuit includes forming a fin comprising semiconductor material, the fin extending above a substrate and extending in a first direction; forming a dielectric layer adjacent to a subfin portion of the fin; forming a sacrificial gate and a sacrificial gate spacer on a sidewall of the sacrificial gate, the sacrificial gate extending over the semiconductor material in the second direction; forming a source or drain region at one end of the fin; forming a conductive contact on the source or drain region (e.g., and/or on sidewalls of the source or drain region, and/or extending within the source or drain region); removing the sacrificial gate and forming a gate structure on the dielectric layer in place of the sacrificial gate; removing the substrate from the backside of the integrated circuit, wherein the removing exposes a bottom surface of the dielectric layer; removing the dielectric layer from the backside of the integrated circuit such that at least a portion of the sacrificial gate spacer is exposed from the backside; and removing the sacrificial gate spacer from the backside of the integrated circuit to form an airgap between the gate structure and the contact.

The techniques can be used with any type of planar or non-planar transistors, including finFETs (sometimes called double-gate transistors, or tri-gate transistors), or nanowire and nanoribbon transistors (sometimes called gate-all-around transistors), or forksheet transistors, to name a few examples. The source and drain regions can be, for example, implantation-doped regions of the fin structure or substrate or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of an airgap or other low-k dielectric structure running along a boundary between a transistor gate structure and an adjacent source or drain contact. The airgap or other low-k dielectric structure may further extend along the side of the gate structure to separate the gate structure from one or both adjacent source/drain trenches.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

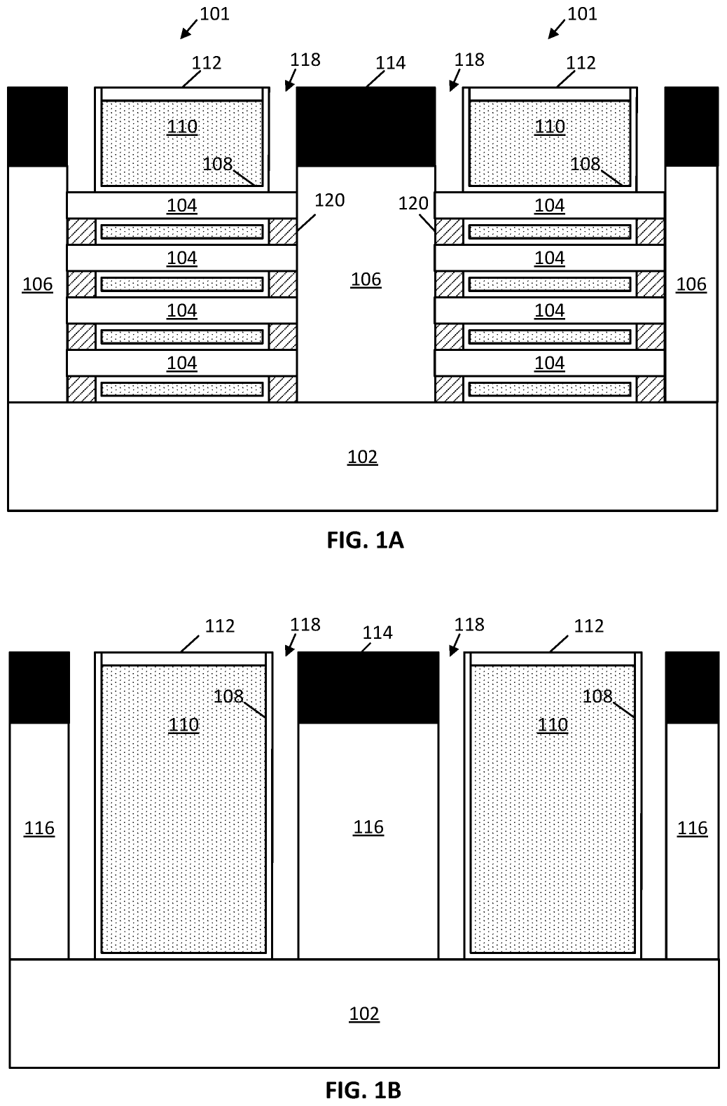

FIG. 1A is a cross-section view taken through various semiconductor devices 101 along a ‘fin’ direction that illustrates the semiconductor bodies extending between source or drain regions of each semiconductor device 101, in accordance with an embodiment of the present disclosure. FIG. 1B illustrates a cross-section view taken parallel to the cross-section from FIG. 1A and into the page (or out of the page, as the case may be), such that it is away from the semiconductor bodies of the transistors but still crosses the gate structures extending over the semiconductor bodies. Each of the semiconductor devices may be, for instance, non-planar metal oxide semiconductor (MOS) transistors, such as tri-gate (e.g., finFET) or gate-all-around (GAA) transistors, although other transistor topologies and types could also benefit from the techniques provided herein. The examples herein illustrate semiconductor devices with a GAA structure (e.g., having nanoribbons or nanowires that extend between source and drain regions). Other examples may have a forksheet structure having a p-type device and an n-type device with semiconductor nanosheets separated by a dielectric spine or structure.

The semiconductor material used in each of the semiconductor devices may be formed from a semiconductor substrate. The one or more semiconductor regions of the devices may include fins that can be, for example, native to the substrate (formed from the substrate itself), such as silicon fins etched from a bulk silicon substrate. Alternatively, the fins can be formed of material deposited onto the substrate. In one such example case, a blanket layer of SiGe can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons and nanosheets during a gate forming process where one type of the alternating layers is selectively etched away so as to liberate the other type of alternating layers within the channel region, so that a gate-all-around process or a forksheet gate process can then be carried out. Again, the alternating layers can be blanket deposited and then etched into fins or deposited into fin-shaped trenches, in some examples.

In some embodiments, the substrate is removed and replaced with one or more backside dielectric layers represented by dielectric base layer 102. Accordingly, dielectric base layer 102 may represent STI regions and any number of backside interconnect layers. According to some embodiments, the dielectric layers of dielectric base layer 102 include any suitable dielectric material, such as silicon dioxide.

Each semiconductor device 101 includes one or more semiconductor regions (also called channel regions), such as one or more nanoribbons 104 extending between epitaxial source or drain regions 106 in the first direction. The term nanoribbon may also encompass other similar shapes such as nanowires or nanosheets. A gate structure extends over the one or more semiconductor regions (e.g., nanoribbons 104) of a given semiconductor device 101 in a second direction (e.g., into and out of the page) to form the transistor gate.

Any of source or drain regions 106 may act as either a source region or a drain region, depending on the application and dopant profile. Any semiconductor materials suitable for source and drain regions can be used (e.g., group IV and group III-V semiconductor materials) for any of the illustrated source or drains regions 106. In any such cases, the composition and doping of source or drain regions 106 may be the same or different, depending on the polarity of the transistors. For example, any semiconductor devices that are p-channel transistors have a high concentration of p-type dopants in the associated source or drain regions 106, and any semiconductor devices that are n-channel transistors have a high concentration of n-type dopants in the associated source or drain regions 106. Example p-type dopants include boron and example n-type dopants include phosphorous. Any number of source and drain configurations and materials can be used. In some examples, n-type source or drain regions include silicon doped with phosphorous and p-type source or drain regions include silicon germanium doped with boron.

The gate structure includes a gate dielectric 108 and a gate electrode 110. Gate dielectric 108 represents any number of dielectric layers present between nanoribbons 104 and gate electrode 110. Gate dielectric 108 may also be present on the surfaces of other structures within the gate trench, such as on a surface of dielectric base layer 102. Gate dielectric 108 may include any suitable gate dielectric material(s). In some embodiments, gate dielectric 108 includes a layer of native oxide material (e.g., silicon dioxide) on the nanoribbons or other semiconductor regions making up the channel region of the devices, and a layer of high-k dielectric material (e.g., hafnium oxide) on the native oxide.

Gate electrode 110 may represent any number of conductive layers on the gate dielectric, such as any metal, metal alloy, or doped polysilicon layers. In some embodiments, gate electrode 110 includes one or more workfunction metals around nanoribbons 104. In some embodiments, one of the semiconductor devices is a p-channel device that includes a workfunction metal having titanium around its nanoribbons and another semiconductor device is an n-channel device that includes a workfunction metal having tungsten around its nanoribbons. Gate electrode 110 may also include a fill metal or other conductive material around the workfunction metals to provide the whole gate electrode structure. According to some embodiments, a dielectric cap 112 may be present over gate electrode 110 within the gate trenches of semiconductor devices 101. Dielectric cap 112, may be any suitable dielectric material, such as silicon nitride.

According to some embodiments, conductive contacts 114 are provided on source or drain regions 106. Conductive contacts 114 can include any suitable conductive material, such as tungsten, molybdenum, ruthenium, cobalt, or other metals. Conductive contacts 114 may be formed together such that they all include the same conductive material. According to some embodiments, dielectric plugs 116 are provided within the source/drain trenches between source or drain regions 106 along the second direction. Dielectric plugs 116 may be any suitable dielectric material, such as silicon dioxide, silicon oxynitride, or silicon oxycarbide. As seen in FIG. 1B, contacts 114 may also be formed over dielectric plugs 116. In some other examples, dielectric plugs 116 extend up the entire height of the source/drain trench (e.g., such that a top surface of dielectric plugs 116 is substantially coplanar with a top surface of dielectric cap 112). While contacts 114 are shown on top of source or drain regions 106 in this example, contacts 114 may also be, or alternatively be, on sidewalls of source or drain regions 106. Also, contacts 114 may extend into source or drain regions 106.

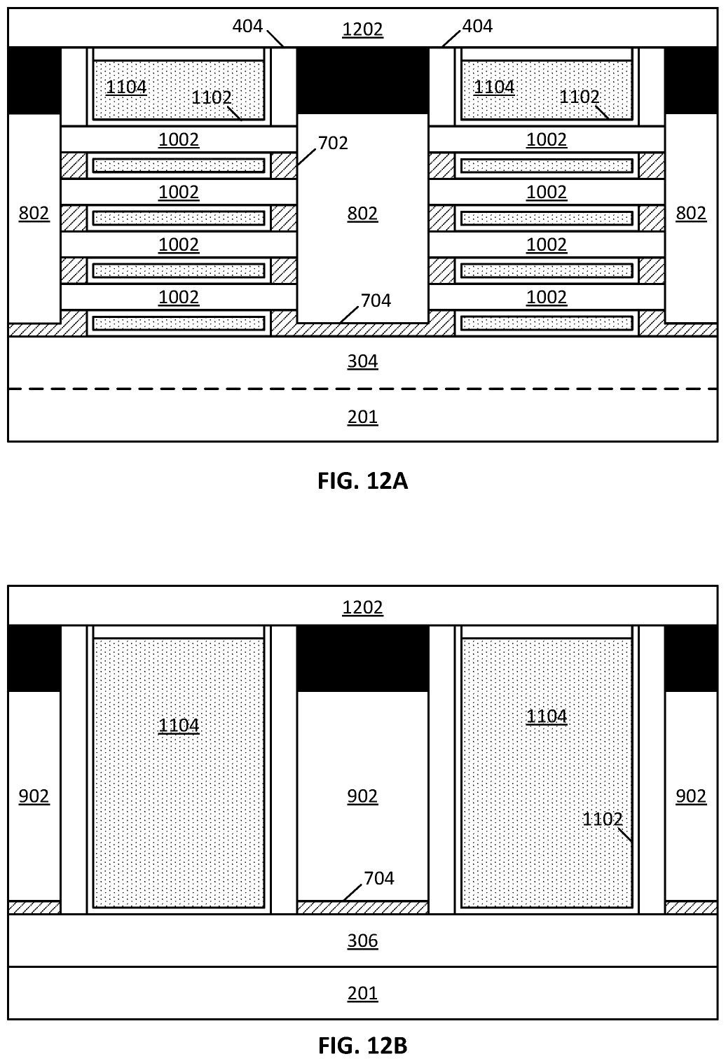

According to some embodiments, an airgap 118 is provided between at least the gate structures and the adjacent contacts 114 along the first direction. Airgap 118 may further extend along the second direction and along a third direction (e.g., a vertical direction or height direction) to separate the gate structures from the adjacent source/drain trenches. According to some embodiments, airgaps 118 have a lateral width in the range of about 5 nm to about 15 nm. In some examples, airgap 118 extends along the second direction for an entire length of the gate structure in the second direction, while in other examples the airgap extends along the second direction for a certain distance (e.g., such as 25 nm or more). Similarly, the airgap 118 may extend along the third direction for an entire height of the gate structure in the third direction, or for a certain distance (e.g., such as 25 nm or more). Airgaps may include an inert gas, such as argon. In some examples, airgaps 118 are substantially devoid of gas and are at vacuum pressure. Although not shown in these figures for clarity, one or more front-side interconnect layers would be formed over airgaps 118 on top of the device to effectively seal off airgaps 118 from the surrounding environment. Example front-side and back-side interconnect structures are shown, for example, in FIGS. 12A-B and 15A-B, respectively. According to some embodiments, inner spacers 120 may be provided to separate adjacent nanoribbons 104 from one another along the third direction (e.g., vertical direction). Inner spacers 120 may include any suitable dielectric material, such as silicon nitride. In an example, inner spacers 120 include a dielectric material that is etch selective with respect to a sacrificial dielectric material used as a placeholder for airgaps 118. Such etch selectivity allows the placeholder material to be selectively removed via an etch process, with little or no removal of the inner spacer 120 material, as further described below. According to some embodiments, inner spacers 120 are substantially aligned with airgaps 118 along a plane extending in the first and third directions.

### Fabrication Methodology

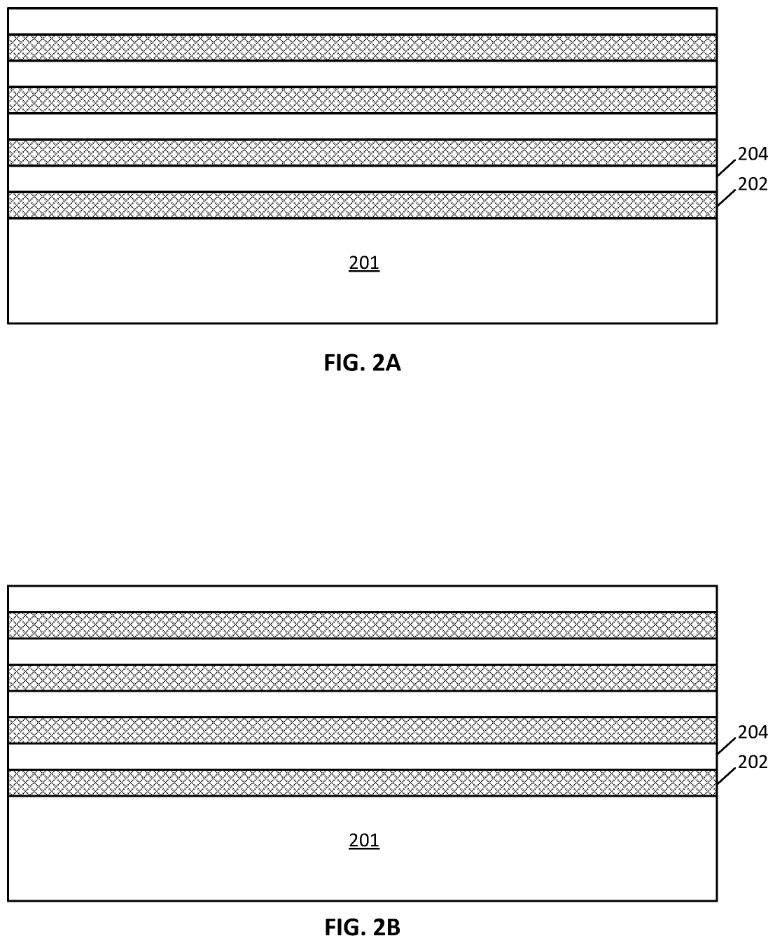

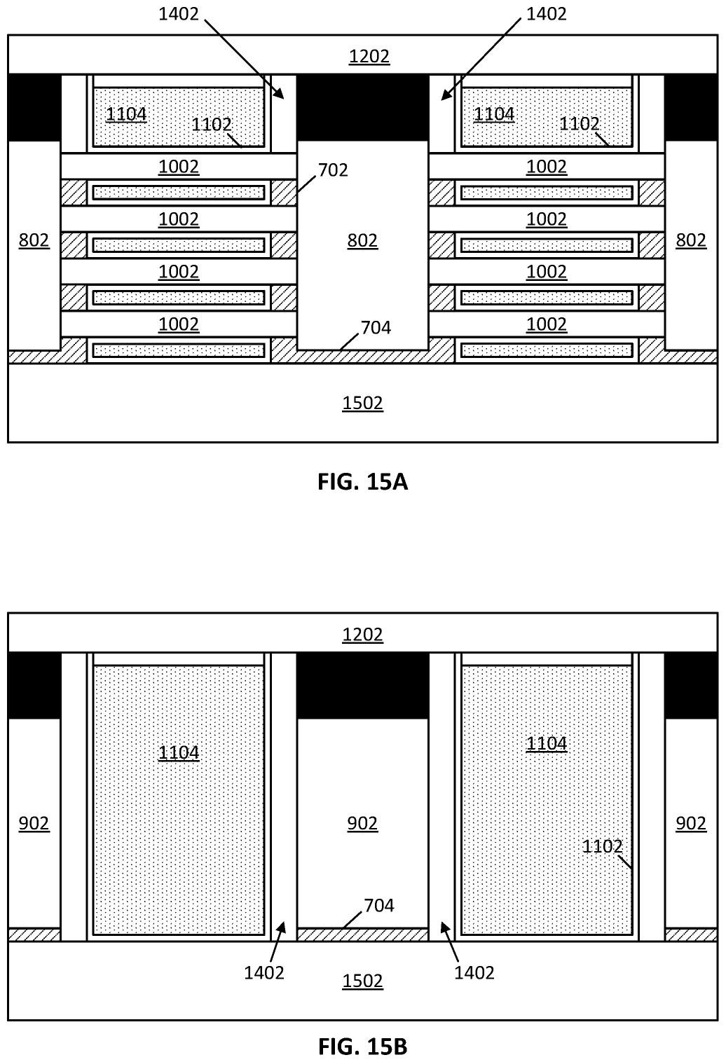

FIGS. 2A-15A and 2B-15B include cross-sectional views that collectively illustrate an example process for forming an integrated circuit configured with a molybdenum-containing workfunction layer, in accordance with an embodiment of the present disclosure. FIGS. 2A-15A represent a similar cross-sectional view as that of FIG. 1A across a series of semiconductor devices, while FIGS. 2B-15B represent a similar cross-sectional view as that of FIG. 1B parallel to the view in FIGS. 2A-15A and away from the semiconductor devices. Each set of figures sharing the same letter shows an example structure that results from the process flow up to that point in time, so the depicted structure evolves as the process flow continues, culminating in the structure shown in FIGS. 15A-15B, which is similar to the structure shown in FIGS. 1A and 1B. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but other materials and process parameters may be used as well, as will be appreciated in light of this disclosure.

FIGS. 2A and 2B each illustrates a cross-sectional view taken through a substrate 201 having a series of material layers formed over a substrate, according to an embodiment of the present disclosure. Alternating material layers may be deposited over substrate 201 including sacrificial layers 202 alternating with semiconductor layers 204. The alternating layers are used to form GAA transistor structures. Any number of alternating sacrificial layers 202 and semiconductor layers 204 may be deposited over substrate 201.

Substrate 201 can be, for example, a bulk substrate including group IV semiconductor material (such as silicon, germanium, or SiGe), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, semiconductor layers 204 have a different material composition than sacrificial layers 202. In some embodiments, semiconductor layers 204 include a semiconductor material suitable for use as a nanoribbon such as silicon (Si), SiGe, germanium, or III-V materials like indium phosphide (InP) or gallium arsenide (GaAs). Sacrificial layers 202 include a material that can be selectively removed relative to semiconductor layers 204. In some examples, for instance, semiconductor layers 204 are silicon and sacrificial layers 202 are SiGe, or vice-versa. In some other examples where SiGe is used in each of semiconductor layers 204 and in sacrificial layers 202, the germanium concentration is different between semiconductor layers 204 and sacrificial layers 202, so as to allow for etch selectivity. For example, semiconductor layers 204 may include a higher germanium content compared to sacrificial layers 202.

While dimensions can vary from one example embodiment to the next, the thickness of each semiconductor layer 204 may be in the range of about 5 nm to about 20 nm, in some examples. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any material deposition technique, such as chemical vapor deposition (CVD), plasma-enhanced chemical vapor deposition (PECVD), physical vapor deposition (PVD), or atomic layer deposition (ALD), or epitaxial growth.

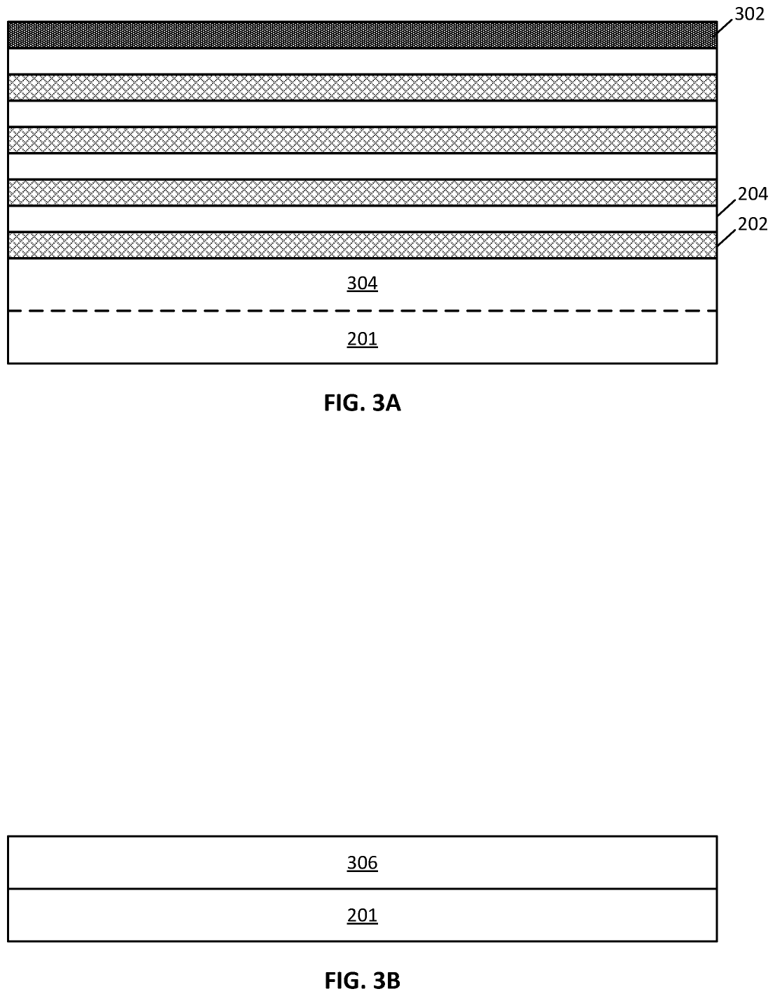

FIGS. 3A and 3B depict the cross-section views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. Cap layer 302 extends along the top of each fin in a first direction, as seen in FIG. 3A.

According to some embodiments, an anisotropic etching process through the layer stack continues into at least a portion of substrate 201. Portions of substrate 201 beneath the fins are not etched and yield subfin regions 304 as illustrated in FIG. 3A. The etched portions of substrate 201 that are not under the fins may be filled with a dielectric fill 306 that acts as shallow trench isolation (STI) between adjacent fins as illustrated in FIG. 3B. Dielectric fill 306 may be any suitable dielectric material such as silicon dioxide. Subfin regions 304 represent remaining portions of substrate 201 flanked by dielectric fill 306, according to some embodiments.

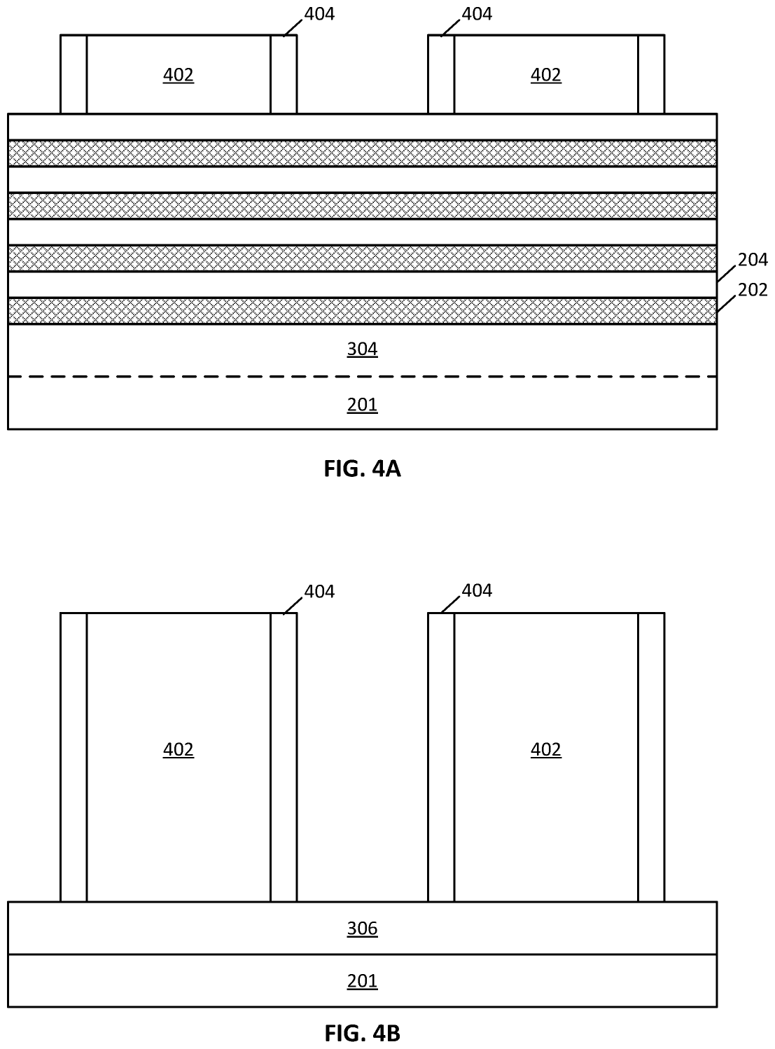

FIGS. 4A and 4B depict cross-section views of the structures shown in FIGS. 3A and 3B following the formation of sacrificial gates 402 and sacrificial spacers 404, according to some embodiments. A gate masking layer may first be patterned in strips that extend orthogonally across each of the fins (e.g., in a second direction) in order to form corresponding sacrificial gates 402 in strips beneath the gate masking layers. Afterwards, the gate masking layers may be removed or may remain as a cap layer above each sacrificial gate 402. According to some embodiments, the sacrificial gate material is removed in all areas not protected by the gate masking layers. Sacrificial gate 402 may be any suitable material that can be selectively removed without damaging the semiconductor material of the fins. In some examples, sacrificial gate 402 includes polysilicon.

According to some embodiments, sacrificial spacers 404 are formed along the sidewalls of sacrificial gates 402. Sacrificial spacers 404 may be conformally deposited (e.g., CVD or ALD)_and then etched back or otherwise removed (e.g., via anisotropic or directional etch) from horizontal surfaces, such that sacrificial spacers 404 remain mostly only on sidewalls of any exposed structures. The width of sacrificial spacers 404 (along the first direction) may vary from one example to the next, but in some cases is in the range of 3 nm to 20 nm. According to some embodiments, sacrificial spacers 404 include a material that can withstand various dielectric, semiconductor, and/or metal etching processes, while being removable using an etching process that causes little damage to surrounding structures. In one example, sacrificial spacers 404 include aluminum oxide.

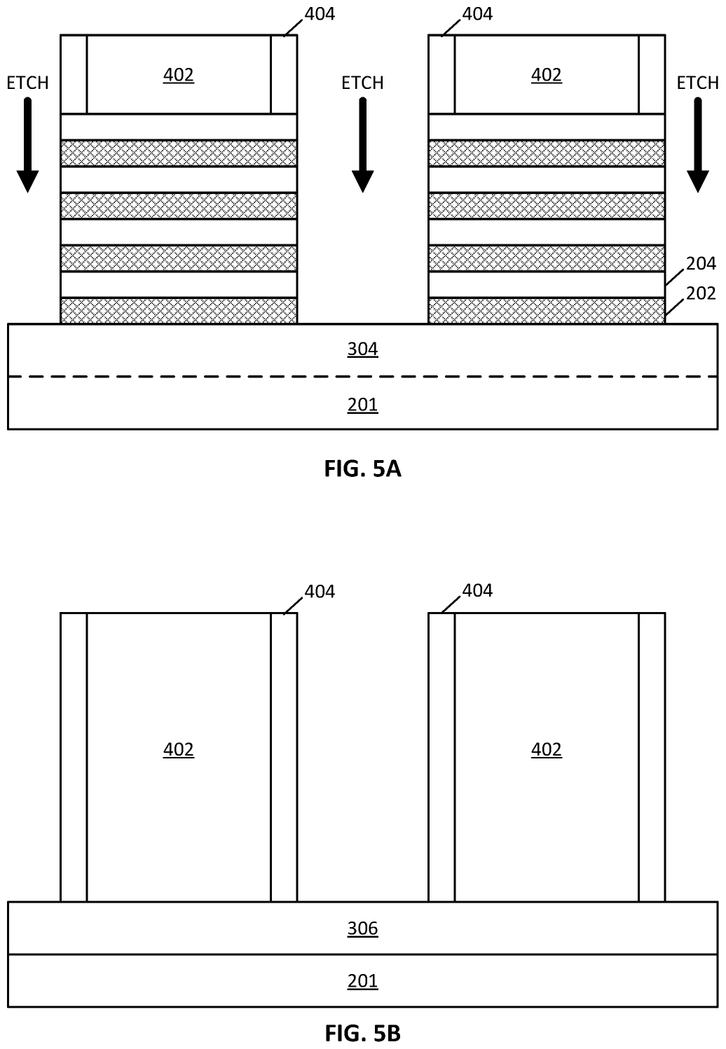

FIGS. 5A and 5B depict cross-section views of the structures shown in FIGS. 4A and 4B following the removal of exposed portions of the fins not protected by sacrificial gates 402 and sacrificial spacers 404, according to some embodiments. The exposed fin portions may be removed using any anisotropic etching process, such as reactive ion etching (RIE) or other directional etch process. The removal of the exposed fin portions creates source or drain trenches that alternate with gate trenches (currently filled with sacrificial gates 402) along the first direction, according to some embodiments. In some embodiments, at least a portion of subfin regions 304 is also removed such that a top surface of subfin regions 304 is recessed below a top surface of dielectric fill 306. The recessed area of subfin regions 304 may be filled with one or more dielectric materials.

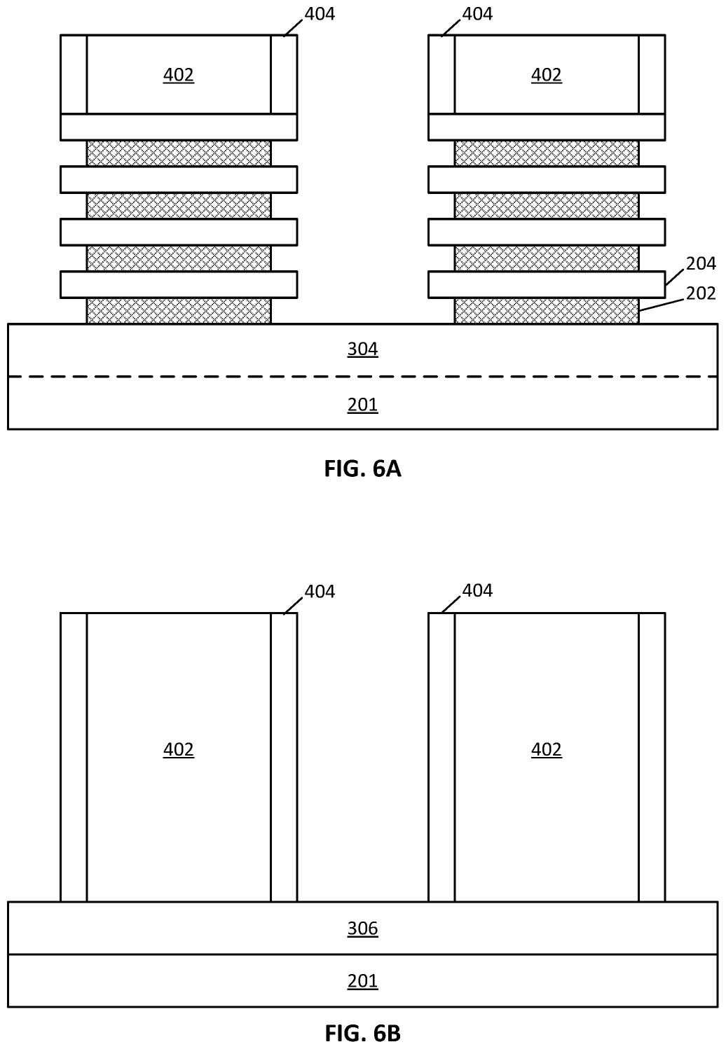

FIGS. 6A and 6B depict cross-section views of the structures shown in FIGS. 5A and 5B following the removal of portions of sacrificial layers 202, according to an embodiment of the present disclosure. An isotropic etching process may be used to selectively recess the exposed ends of each sacrificial layer 202 (e.g., while etching comparatively little of semiconductor layers 204).

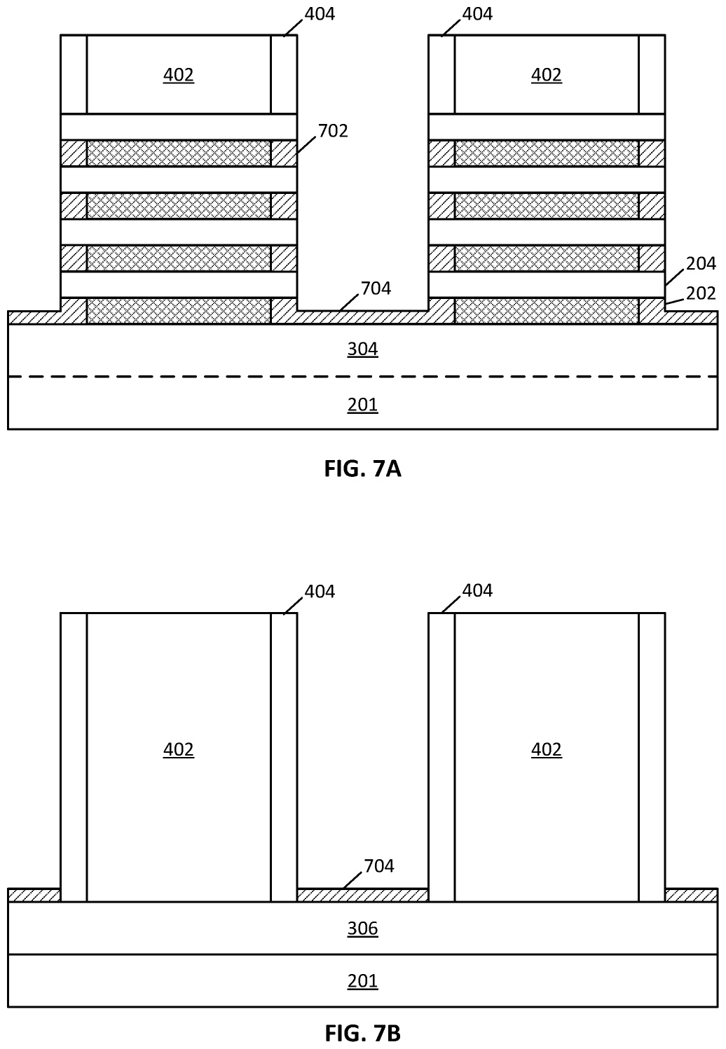

FIGS. 7A and 7B depict cross-section views of the structures shown in FIGS. 6A and 6B following the formation of internal spacers 702, according to an embodiment of the present disclosure. Internal spacers 702 may be any suitable dielectric material, such as silicon nitride, that exhibits high etch selectively to semiconductor materials, such as silicon and/or silicon germanium. In an example, internal spacers 702 may include a dielectric material that is etch selective with respect to dielectric material of sacrificial spacers 404. As described above, such etch selectivity allows sacrificial spacers 404 to be selectively removed, with little or no removal of internal spacers 702. In one such example, for instance, internal spacers 702 include silicon nitride and sacrificial spacers 404 include aluminum oxide. Other examples may include other combinations of etch selective materials (e.g., nitride/carbide, carbide/oxide, or other combination of nitride/oxide/carbide dielectric materials that provides etch selectivity). Internal spacers 702 may be, for example, conformally deposited over the sides of the fin structure using a conformal deposition process like CVD or ALD and then etched back using an isotropic etching process to expose the ends of semiconductor layers 204. According to some embodiments, internal spacers 702 have a similar width (e.g., along the first direction) to sacrificial spacers 404, but they need not be the same width. Note that internal spacers 702 may be formed around the ends of semiconductor layers 204 and not along other edges of the gate trench away from semiconductor layers 204 (as shown in FIG. 7B), according to some embodiments.

According to some embodiments, portions of the dielectric material used to form inner spacers 702 remains at the bottom of the source/drain trenches as a bottom dielectric layer 704, as further shown in FIGS. 7A-B. Bottom dielectric layer 704 may be removed in other examples. However, the existence of bottom dielectric layer 704 may be beneficial to isolate the subsequent source or drain regions from subfin regions 304.

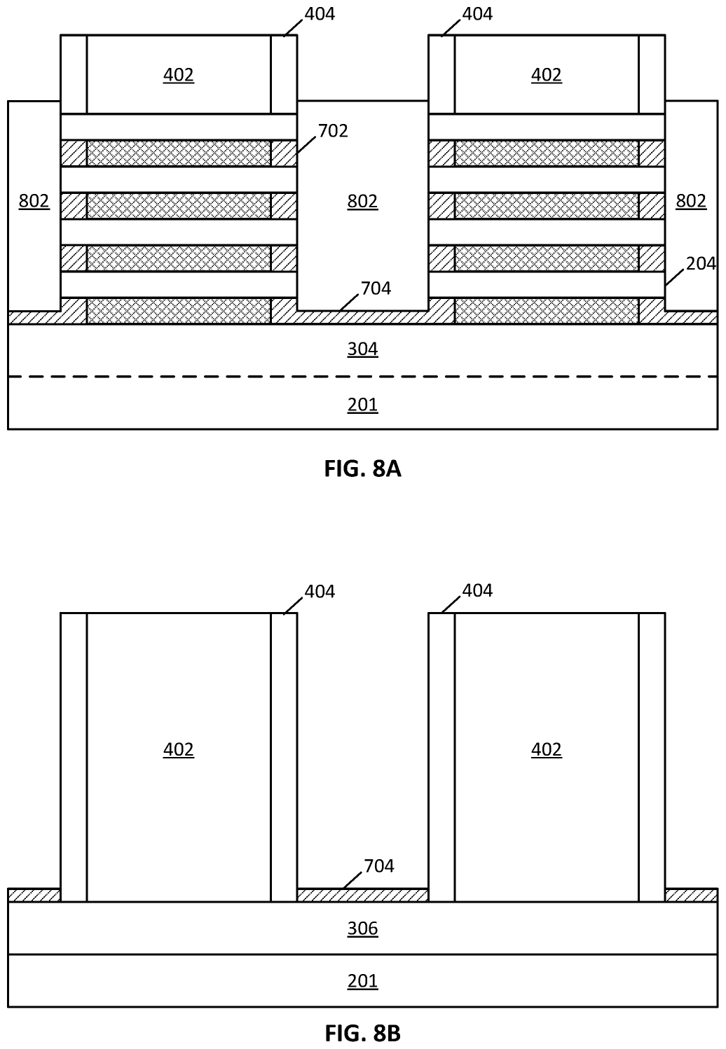

FIGS. 8A and 8B depict cross-section views of the structure shown in FIGS. 7A and 7B, respectively, following the formation of source or drain regions 802 within the source/drain trenches, according to some embodiments. Source or drain regions 802 may be formed in the areas that had been previously occupied by the exposed fins between sacrificial spacers 404. According to some embodiments, source or drain regions 802 are epitaxially grown from the exposed semiconductor material at the ends of semiconductor layer(s) 204. In other examples, source or drain regions 802 are doped portions of a fin structure or other semiconductor substrate region. In some example embodiments, source or drain regions 802 are n-channel source or drain regions (e.g., epitaxial silicon with n-type dopants) or p-channel source or drain regions (e.g., epitaxial SiGe with p-type dopants).

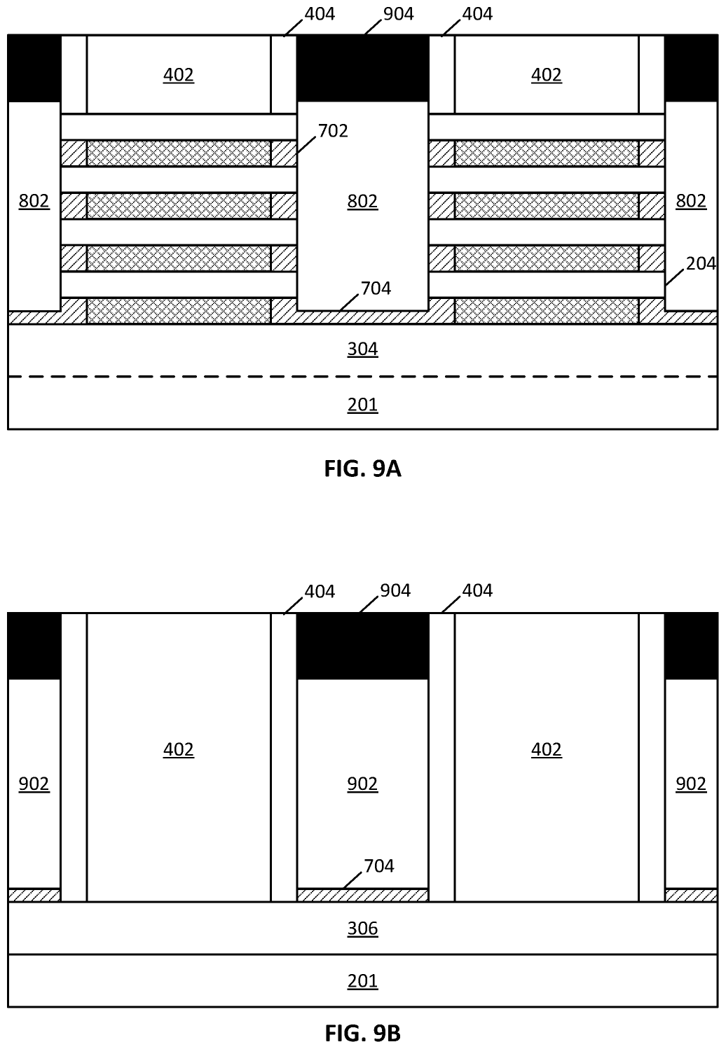

FIGS. 9A and 9B depict cross-section views of the structure shown in FIGS. 8A and 8B, respectively, following the formation of dielectric plugs 902 within the source/drain trenches and contacts 904 over source or drain regions 802, according to some embodiments. Dielectric plugs 902 may be provided between adjacent source or drain regions 802 along a given source/drain trench in the second direction. In some examples, dielectric plugs 902 occupy a remaining volume within the source/drain trench around and possibly over portions of source or drain regions 802. Dielectric plugs 902 may be any suitable dielectric material, such as silicon dioxide. In some examples, dielectric plugs 902 extends up to and planar with a top surface of sacrificial spacers 404 (e.g., following a polishing procedure).

According to some embodiments, contacts 904 may be formed over or otherwise on one or more surfaces of source or drain regions 802. For instance, in some examples, contacts 904 may be on top and/or sidewall surfaces of source or drain regions 802. In still other examples, contacts 904 may also, or alternatively, extend into source or drain regions 802. Contacts 904 may include any suitable conductive material, such as tungsten, cobalt, molybdenum, or ruthenium, for making electrical contact with the underlying source or drain regions 802. In some embodiments, dielectric plugs 902 are first formed around and over source or drain regions 802 and are then recessed within the source/drain trenches to expose at least a top surface of source or drain regions 802. The recessed area may be filled with conductive material to form contacts 904. In some examples, contacts 904 extend in the second direction over at least a portion of dielectric plug 902 as shown in FIG. 9B. As described above, contacts 904 may also extend into the underlying source or drain regions 802 and/or be on one or more sidewalls of the source or drain regions 802. According to some embodiments, a dielectric liner is formed first on the sidewalls of sacrificial spacers 404 prior to the formation of contacts 904. Accordingly, contacts 904 may have the dielectric liner along its edges that face sacrificial spacers 404. The dielectric liner may include any suitable dielectric material, such as silicon nitride.

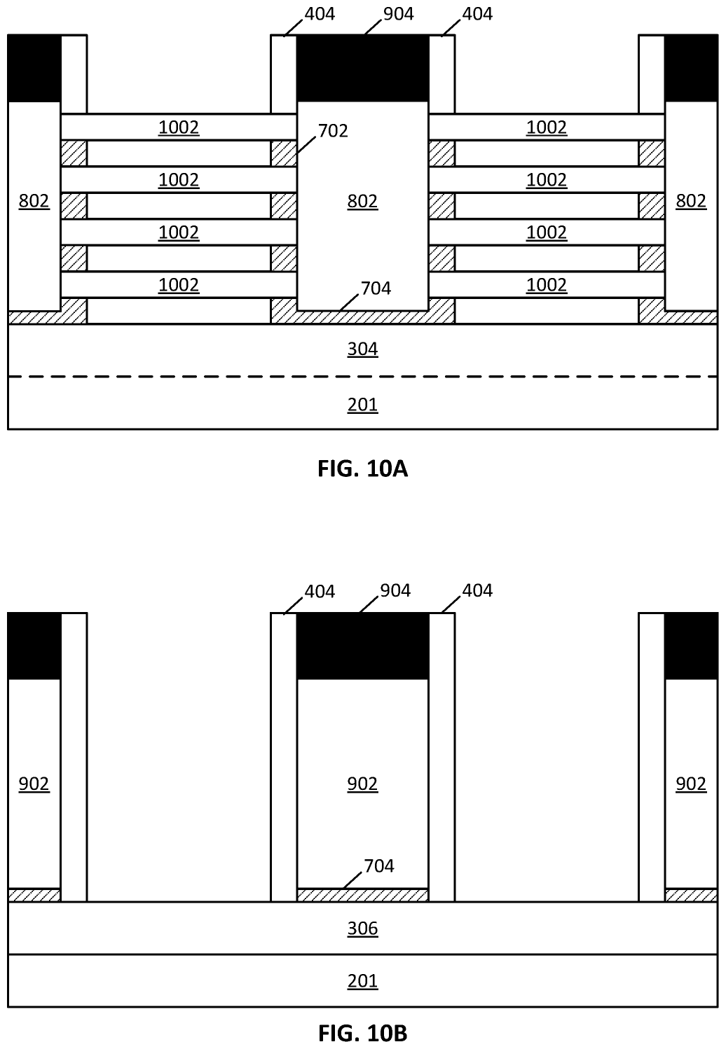

FIGS. 10A and 10B depict cross-section views of the structure shown in FIGS. 9A and 9B, respectively, following the removal of sacrificial gates 402 and sacrificial layers 202, according to some embodiments. In examples where gate masking layers are still present, they may be removed at this time. Once sacrificial gates 402 are removed, the fins extending between sacrificial spacers 404 are exposed.

In the example where the fins include alternating sacrificial layers 202 and semiconductor layers 204, sacrificial layers 202 are selectively removed to leave behind nanoribbons 1002 that extend between corresponding source or drain regions 802. Each vertical set of nanoribbons 1002 represents the semiconductor region (also called channel region) of a different semiconductor device. It should be understood that nanoribbons 1002 may also be nanowires or nanosheets. Sacrificial gates 402 and sacrificial layers 202 may be removed using the same isotropic etching process or different isotropic etching processes.

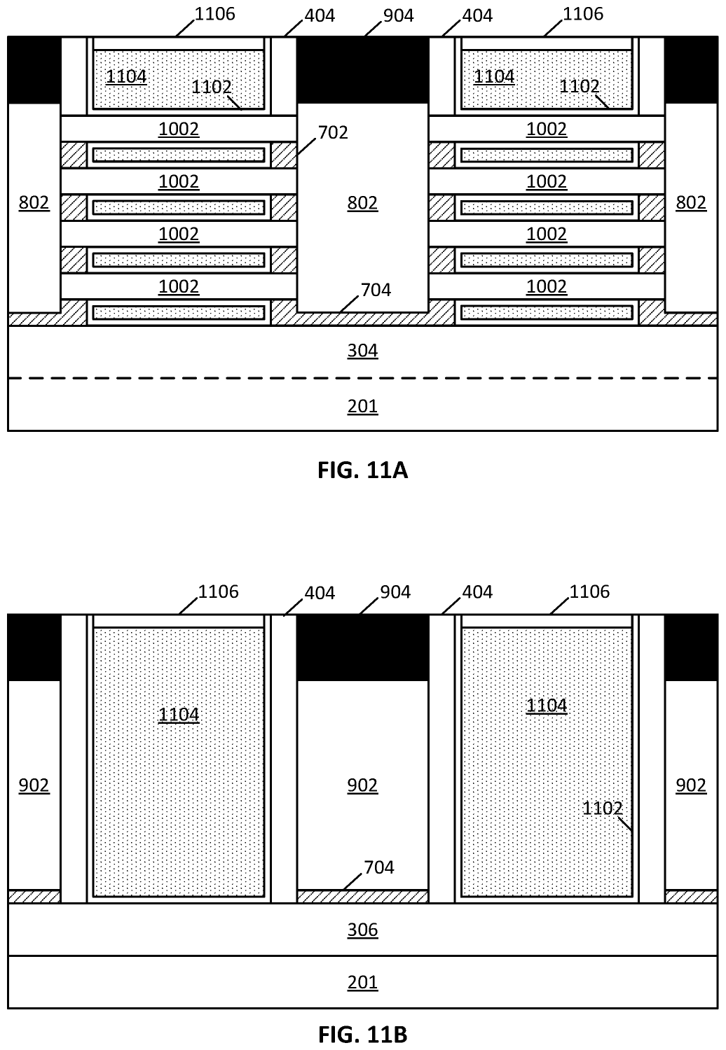

FIGS. 11A and 11B depict cross-section views of the structure shown in FIGS. 10A and 10B, respectively, following the formation of gate structures within the gate trenches, according to some embodiments. The gate structure includes a gate dielectric 1102 and a gate electrode 1104. Gate dielectric 1102 may be formed around nanoribbons 1002 and along any exposed surfaces within the gate trenches, such as along sidewalls of sacrificial spacers 404. Gate dielectric 1102 may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 1102 includes a layer of hafnium oxide with a thickness in the range of about 1 nm to about 5 nm. In some embodiments, gate dielectric 1102 may include one or more silicates (e.g., titanium silicate, tungsten silicate, niobium silicate, and silicates of other transition metals). In some cases, gate dielectric 1102 includes a first layer on nanoribbons 1002, and a second layer on the first layer. The first layer can be, for instance, an oxide of the semiconductor material of nanoribbons 1002 (e.g., silicon dioxide) and the second layer can be a high-k dielectric material (e.g., hafnium oxide or aluminum oxide). Any excess gate dielectric may be removed from the top surface of structure, for instance, via a polishing process (e.g., chemical mechanical planarization, CMP).

Gate electrode 1104 may be deposited over gate dielectric 1102 and can include any conductive structure. In some embodiments, gate electrode 1104 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 1104 may include, for instance, one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates. A metal fill may be included around the work function layers to take up the remaining volume within the gate trenches. The metal fill may include tungsten, ruthenium, molybdenum, or cobalt.

According to some embodiments, a gate cap 1106 may be formed by first recessing gate electrode 1104 and filling the recess with a dielectric material. The dielectric material may then be polished such that its top surface is substantially coplanar with sacrificial spacers 404. Gate cap 1106 may be any suitable dielectric material, such as silicon nitride.

FIGS. 12A and 12B depict cross-section views of the structure shown in FIGS. 11A and 11B, respectively, following the formation of a topside interconnect structure 1202, according to some embodiments. Topside interconnect structure 1202 may represent any number of interconnect layers with each interconnect layer having a layer of dielectric material and any number of conductive vias and/or conductive traces. The dielectric material of the various interconnect layer can by any suitable dielectric material, such as silicon dioxide. The formation of topside interconnect structure 1202 is often referred to as back-end-of-the-line (BEOL) processing. According to some embodiments, a lowest interconnect layer of topside interconnect structure 1202 directly contacts a top surface of sacrificial spacers 404.

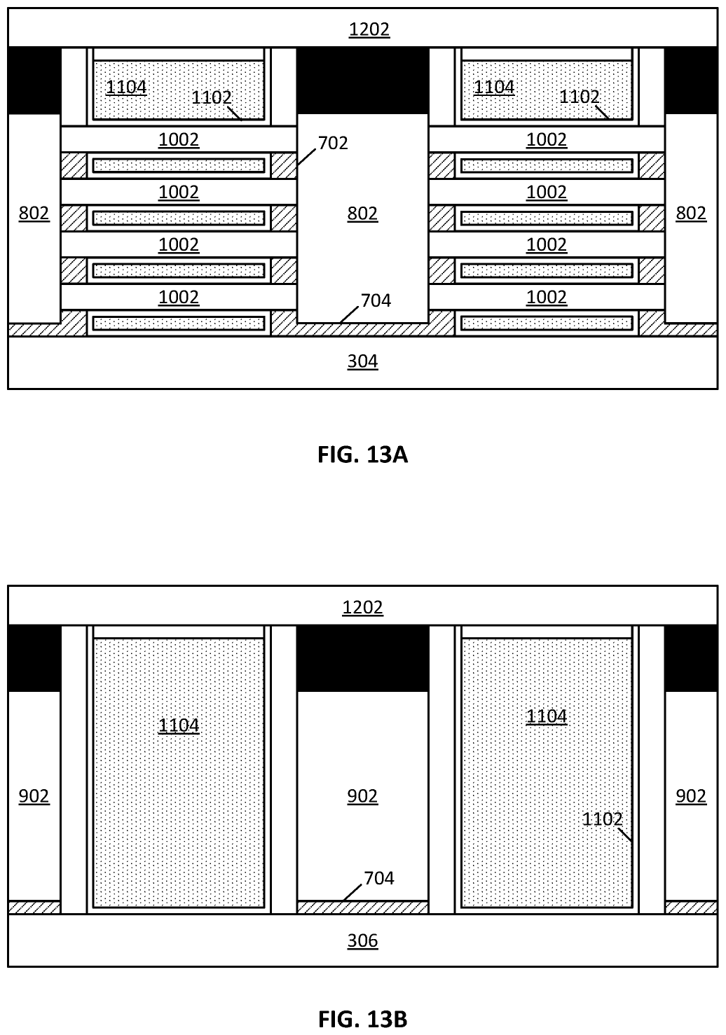

FIGS. 13A and 13B depict cross-section views of the structure shown in FIGS. 12A and 12B, respectively, following the backside removal of substrate 201, according to some embodiments. Once all front-side processes have been performed across the integrated circuit, substrate 201 may be removed via any arrangement of grinding, polishing, and/or chemical etching processes. According to some embodiments, all materials are removed from the backside up until at least a bottom surface of dielectric fill 306 is exposed, which may also expose a bottom surface of the adjacent subfins regions 304 across the integrated circuit.

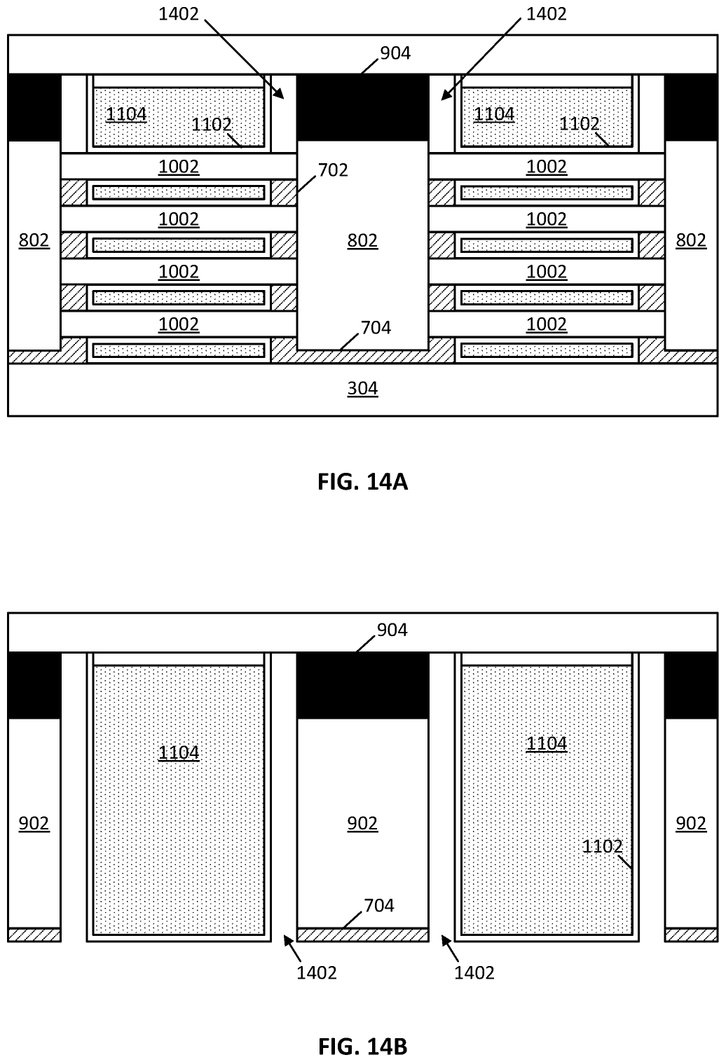

FIGS. 14A and 14B depict cross-section views of the structure shown in FIGS. 13A and 13B, respectively, following the removal of dielectric fill 306 from the backside and subsequent removal of sacrificial spacers 404, according to some embodiments. Dielectric fill 306 may be removed using any suitable isotropic etching process, and preferably using an etch chemistry that does not etch (or etches relatively little of) the exposed gate dielectric 1102. In examples where dielectric fill 306 is silicon dioxide and gate dielectric 1102 is a high-k dielectric material, such as hafnium oxide, certain etch chemistries may be employed to selectively remove the silicon dioxide material.

According to some embodiments, following the removal of dielectric fill 306, the bottom surface of sacrificial spacers 404 is exposed. In an example, an ammonia-based isotropic etching process may be used to selectively remove sacrificial spacers 404 (e.g. aluminum oxide) to leave behind airgaps 1402. Accordingly, airgaps 1402 may have substantially the same lateral thickness as sacrificial spacers 404 (e.g., in the range of about 3 nm to about 20 nm). As shown in FIG. 14A, sacrificial spacers 404 may also be removed in the area between contact 904 and the adjacent gate structure. Since airgap 1402 has the lowest possible or an otherwise very low dielectric constant (e.g., around 1.0), the parasitic capacitance between contact 904 and the adjacent gate structure is reduced. In some embodiments, a low-k dielectric material (e.g., porous or low-density dielectric material) may be deposited within airgaps 1402 from the backside. Pinch-off may occur during such deposition, so as to provide a combination of airgap and low-k dielectric fill, in some examples. In some embodiments, the dielectric liner discussed above with reference to FIGS. 9A and 9B remains on the edges of contact 904, such that airgaps 1402 are directly between gate dielectric 1102 and the dielectric liner.

FIGS. 15A and 15B depict cross-section views of the structure shown in FIGS. 14A and 14B, respectively, following the formation of a backside interconnect structure 1502, according to some embodiments. Backside interconnect structure 1502 may represent any number of interconnect layers with each interconnect layer having a layer of dielectric material and any number of conductive vias and/or conductive traces. The dielectric material of the various interconnect layer can by any suitable dielectric material, such as silicon dioxide. In some embodiments, subfin regions 304 are removed using any suitable semiconductor etching process prior to the formation of backside interconnect structure 1502. According to some embodiments, backside interconnect structure extends over the bottom gaps of airgaps 1402, effectively sealing airgaps 1402. In this way, airgaps 1402 may include an inert gas, such as argon, used during the formation of the first layer of backside interconnect structure 1502. Airgaps 1402 may also be substantially free of gaseous elements. According to some embodiments, airgaps 1402 are brought to a vacuum pressure during the formation of the first layer of backside interconnect structure 1502, and remain at the vacuum pressure after being sealed.

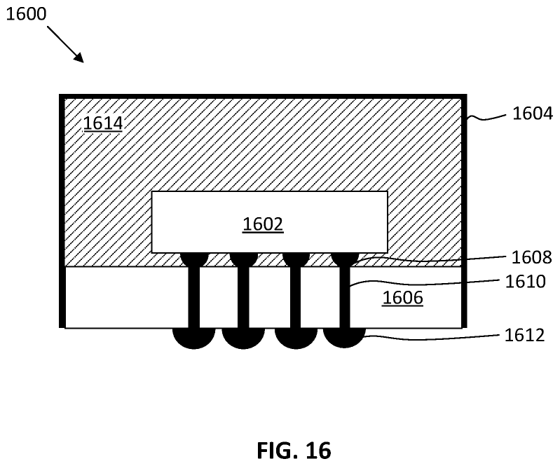

FIG. 16 illustrates an example embodiment of a chip package 1600, in accordance with an embodiment of the present disclosure. As can be seen, chip package 1600 includes one or more dies 1602. One or more dies 1602 may include at least one integrated circuit having semiconductor devices, such as any of the semiconductor devices disclosed herein. One or more dies 1602 may include any other circuitry used to interface with other devices formed on the dies, or other devices connected to chip package 1600, in some example configurations.

As can be further seen, chip package 1600 includes a housing 1604 that is bonded to a package substrate 1606. The housing 1604 may be any standard or proprietary housing, and may provide, for example, electromagnetic shielding and environmental protection for the components of chip package 1600. The one or more dies 1602 may be conductively coupled to a package substrate 1606 using connections 1608, which may be implemented with any number of standard or proprietary connection mechanisms, such as solder bumps, ball grid array (BGA), pins, or wire bonds, to name a few examples. Package substrate 1606 may be any standard or proprietary package substrate, but in some cases includes a dielectric material having conductive pathways (e.g., including conductive vias and lines) extending through the dielectric material between the faces of package substrate 1606, or between different locations on each face. In some embodiments, package substrate 1606 may have a thickness less than 1 millimeter (e.g., between 0.1 millimeters and 0.5 millimeters), although any number of package geometries can be used. Additional conductive contacts 1612 may be disposed at an opposite face of package substrate 1606 for conductively contacting, for instance, a printed circuit board (PCB). One or more vias 1610 extend through a thickness of package substrate 1606 to provide conductive pathways between one or more of connections 1608 to one or more of contacts 1612. Vias 1610 are illustrated as single straight columns through package substrate 1606 for ease of illustration, although other configurations can be used (e.g., damascene, dual damascene, through-silicon via, or an interconnect structure that meanders through the thickness of substrate 1606 to contact one or more intermediate locations therein). In still other embodiments, vias 1610 are fabricated by multiple smaller stacked vias, or are staggered at different locations across package substrate 1606. In the illustrated embodiment, contacts 1612 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1612, to inhibit shorting.

In some embodiments, a mold material 1614 may be disposed around the one or more dies 1602 included within housing 1604 (e.g., between dies 1602 and package substrate 1606 as an underfill material, as well as between dies 1602 and housing 1604 as an overfill material). Although the dimensions and qualities of the mold material 1614 can vary from one embodiment to the next, in some embodiments, a thickness of mold material 1614 is less than 1 millimeter. Example materials that may be used for mold material 1614 include epoxy mold materials, as suitable. In some cases, the mold material 1614 is thermally conductive, in addition to being electrically insulating.

### Methodology

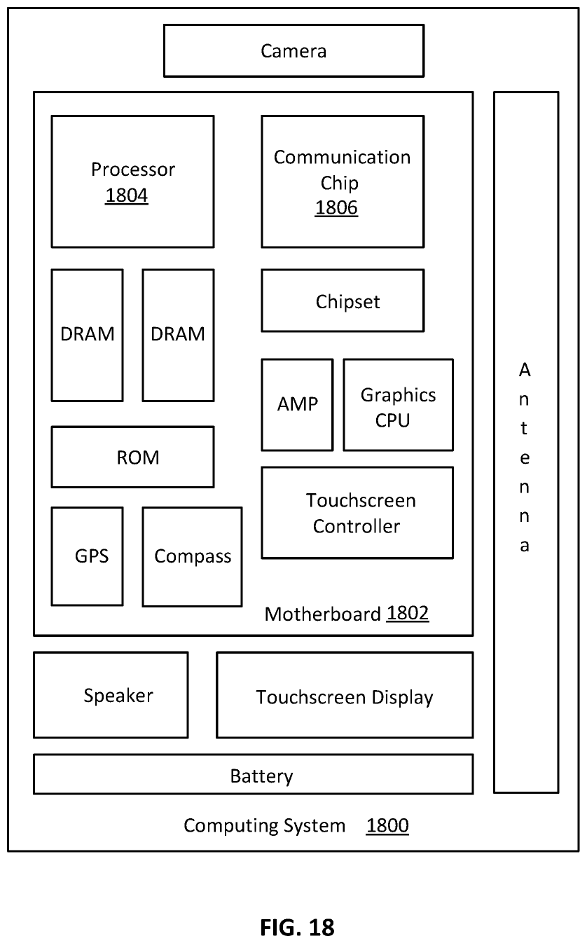

FIG. 18 is a flow chart of a method 1700 for forming at least a portion of an integrated circuit, according to an embodiment. Various operations of method 1700 may be illustrated in FIGS. 2A-15A and 2B-15B. However, the correlation of the various operations of method 1700 to the specific components illustrated in the aforementioned figures is not intended to imply any structural and/or use limitations. Rather, the aforementioned figures provide one example embodiment of method 1700. Other operations may be performed before, during, or after any of the operations of method 1700. For example, method 1700 does not explicitly describe various standard processes that are usually performed to form transistor structures. Some of the operations of method 1700 may be performed in a different order than the illustrated order.

Method 1700 begins with operation 1702 where a plurality of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of SiGe can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches, according to some examples. The fins may also include a cap structure over each fin that is used to define the locations of the fins during, for example, an RIE process. The cap structure may be a dielectric material, such as silicon nitride.

According to some embodiments, a dielectric fill is formed around subfin portions of the one or more fins. In some embodiments, the dielectric fill extends between each pair of adjacent parallel fins and runs lengthwise in the same direction as the fins. In some embodiments, the anisotropic etching process that forms the fins also etches into a portion of the substrate and the dielectric fill may be formed within the recessed portions of the substrate. Accordingly, the dielectric fill acts as shallow trench isolation (STI) between adjacent fins. The dielectric fill may be any suitable dielectric material, such as silicon dioxide. Lower portions of the fins adjacent to the dielectric fill may be identified as the subfins.

Method 1700 continues with operation 1704 where sacrificial gates are formed over the fins. The sacrificial gates may be patterned using gate masking layers in strips that run orthogonally over the fins and parallel to one another (e.g., forming a cross-hatch pattern). The gate masking layers may be any suitable hard mask material, such as CHM or silicon nitride. The sacrificial gates themselves may be formed from any suitable material that can be selectively removed at a later time without damaging the semiconductor material of the fins. In one example, the sacrificial gates include polysilicon.

According to some embodiments, sacrificial spacers are also formed on sidewalls of at least the sacrificial gates. The sacrificial spacers may be deposited and then etched back such that the spacer structures remain mostly only on sidewalls of any exposed structures. In some cases, the sacrificial spacers may also be formed along sidewalls of the exposed fins running orthogonally between the strips of sacrificial gates. According to some embodiments, the sacrificial spacers include a material that is intended to withstand various dielectric, semiconductor, and metal etching processes while being removed at a layer time. In one example, the sacrificial spacers include aluminum oxide.

Method 1700 continues with operation 1706 where exposed portions of the fins are removed to form source/drain trenches. Any exposed portions of the fins not covered by the sacrificial gates or spacer structures may be removed using any anisotropic etching process, such as reactive ion etching (RIE). Sacrificial layers of the fins may be recessed (e.g., via isotropic etch process) followed by deposition of internal spacers (e.g., silicon nitride), as described above.

Method 1700 continues with operation 1708 where source or drain regions are formed at opposite ends of the fins within the source/drain trenches. The source or drain regions may be formed in the areas that had been previously occupied by the exposed fins between the spacer structures. According to some embodiments, the source or drain regions are epitaxially grown from the exposed semiconductor material of the fins (or nanoribbons, nanowires or nanosheets, as the case may be) along the exterior walls of the spacer structures. In some example embodiments, the source or drain regions are NMOS source or drain regions (e.g., epitaxial silicon with n-type dopants) or PMOS source or drain regions (e.g., epitaxial SiGe with p-type dopants). Dielectric plugs may be formed between and possibly over the source or drain regions along a given source/drain trench. The dielectric plugs may be any suitable dielectric material, such as silicon dioxide. In some examples, the dielectric plugs extend over the source or drain regions up to and planar with a top surface of the spacer structures. The dielectric plugs also act as an electrical insulator between adjacent source or drain regions, although some adjacent source or drain regions may have merged together during their growth.

Method 1700 continues with operation 1710 where contacts are formed on the source or drain regions. The contacts may include any suitable conductive material, such as tungsten, molybdenum, ruthenium, or cobalt. The dielectric plugs over the source or drain regions may be recessed to expose the source or drain regions prior to forming the contacts within the recessed area. The contacts may include any number of different conductive materials and may extend over the top surfaces of any number of source or drain regions within the source/drain trench. As described above, the contacts may also extend into the underlying source or drain regions and/or be on one or more sidewalls of the source or drain regions. The interface topology between the contact and the source or drain region can vary from one example to the next.

Method 1700 continues with operation 1712 where the sacrificial gate is replaced with a gate structure. According to some embodiments, the sacrificial gate may be removed along with any sacrificial layers within the exposed fins between the spacer structures (in the case of GAA structures). A gate structure may then be formed in place of the sacrificial gate. The gate structure may include both a gate dielectric and a gate electrode. The gate dielectric is first formed over the exposed semiconductor regions between the spacer structures followed by forming the gate electrode within the remainder of the gate trench between the spacer structures, according to some embodiments. The gate dielectric may include any number of dielectric layers deposited using a CVD process, such as ALD. The gate electrode can include any conductive material, such as a metal, metal alloy, or polysilicon. The gate electrode may be deposited using electroplating, electroless plating, CVD, ALD, PECVD, or PVD, to name a few examples.

Method 1700 continues with operation 1714 where any BEOL processing is completed. This processing may involve the formation of any number of topside interconnect layers with each interconnect layer having a layer of dielectric material and any number of conductive vias and/or conductive traces. The dielectric material of the various interconnect layer can by any suitable dielectric material, such as silicon dioxide. According to some embodiments, one of the topside interconnect layers is formed directly on a top surface of the sacrificial spacers.

Method 1700 continues with operation 1716 where the substrate and dielectric fill are removed from the backside of the structure. Once all front-side processes have been performed across the integrated circuit, the substrate may be removed via any arrangement of grinding, polishing, and/or chemical etching processes. According to some embodiments, all materials are removed from the backside up until at least a bottom surface of the dielectric fill between the subfins is exposed. The exposed dielectric fill may then be removed using any suitable isotropic etching process.

Method 1700 continues with operation 1718 where the sacrificial spacers are removed from the backside of the structure. An ammonia-based isotropic etching process may be used to selectively remove the sacrificial spacers to leave behind airgaps. Accordingly, the airgaps may have substantially the same lateral thickness as the sacrificial spacers (e.g., in the range of about 3 nm to about 20 nm). According to some embodiments, the sacrificial spacers are removed in regions between the source/drain contacts and adjacent gate structures to reduce the parasitic capacitance between those conductive structures. In some embodiments, a low-k dielectric material (e.g., lower than silicon dioxide) is deposited within the airgaps. In some examples, the regions once occupied by the sacrificial spacers may include both airgaps and a low-k dielectric material.

### Example System

FIG. 18 is an example computing system implemented with one or more of the integrated circuit structures as disclosed herein, in accordance with some embodiments of the present disclosure. As can be seen, the computing system 1800 houses a motherboard 1802. The motherboard 1802 may include a number of components, including, but not limited to, a processor 1804 and at least one communication chip 1806, each of which can be physically and electrically coupled to the motherboard 1802, or otherwise integrated therein. As will be appreciated, the motherboard 1802 may be, for example, any printed circuit board (PCB), whether a main board, a daughterboard mounted on a main board, or the only board of system 1800, etc.

Depending on its applications, computing system 1800 may include one or more other components that may or may not be physically and electrically coupled to the motherboard 1802. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1800 may include one or more integrated circuit structures or devices configured in accordance with an example embodiment (e.g., a module including an integrated circuit device on a substrate, the substrate having one or more semiconductor devices that include a gate structure which includes at least one layer having molybdenum, as variously provided herein). In some embodiments, multiple functions can be integrated into one or more chips (e.g., for instance, note that the communication chip 1806 can be part of or otherwise integrated into the processor 1804).

The communication chip 1806 enables wireless communications for the transfer of data to and from the computing system 1800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1806 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1800 may include a plurality of communication chips 1806. For instance, a first communication chip 1806 may be dedicated to shorter range wireless communications such as Wi-Fi and Bluetooth and a second communication chip 1806 may be dedicated to longer range wireless communications such as GPS, EDGE, GPRS, CDMA, WiMAX, LTE, Ev-DO, and others.

The processor 1804 of the computing system 1800 includes an integrated circuit die packaged within the processor 1804. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1806 also may include an integrated circuit die packaged within the communication chip 1806. In accordance with some such example embodiments, the integrated circuit die of the communication chip includes one or more semiconductor devices as variously described herein. As will be appreciated in light of this disclosure, note that multi-standard wireless capability may be integrated directly into the processor 1804 (e.g., where functionality of any chips 1806 is integrated into processor 1804, rather than having separate communication chips). Further note that processor 1804 may be a chip set having such wireless capability. In short, any number of processor 1804 and/or communication chips 1806 can be used. Likewise, any one chip or chip set can have multiple functions integrated therein.

In various implementations, the computing system 1800 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1800 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a semiconductor device having a semiconductor region extending in a first direction from a source or drain region and a gate structure extending in a second direction over the semiconductor region, a contact on a surface of the source or drain region, and an airgap between an upper portion of the gate structure and the contact. The airgap has a lateral width along the first direction between the upper portion of the gate structure and the contact.

Example 2 includes the integrated circuit of Example 1, wherein the contact comprises tungsten, cobalt, ruthenium, or molybdenum.

Example 3 includes the integrated circuit of Example 1 or 2, wherein the gate structure comprises a gate dielectric and a gate electrode on the gate dielectric, and the integrated circuit further comprises a dielectric liner along outside edges of the contact.

Example 4 includes the integrated circuit of Example 3, wherein the gate dielectric comprises a high-k dielectric material and the dielectric liner comprises silicon and nitrogen.

Example 5 includes the integrated circuit of Example 3 or 4, wherein the airgap is directly between the gate dielectric of the gate structure and the dielectric liner.

Example 6 includes the integrated circuit of any one of Examples 3-5, wherein the airgap is directly between the gate dielectric of the gate structure and the dielectric liner.

Example 7 includes the integrated circuit of any one of Examples 1-6, wherein the lateral width of the airgap is in the range about 3 nm to about 20 nm.

Example 8 includes the integrated circuit of any one of Examples 1-7, wherein the semiconductor device is a first semiconductor device, the semiconductor region is a first semiconductor region, the gate structure is a first gate structure, and the airgap is a first airgap. The integrated circuit further includes a second semiconductor device having a second semiconductor region extending in the first direction from the source or drain region and a second gate structure extending in the second direction over the second semiconductor region, and a second airgap between an upper portion of the second gate structure and the contact. The second airgap has a lateral width along the first direction between the upper portion of the second gate structure and the contact.

Example 9 includes the integrated circuit of Example 8, wherein the lateral width of the first airgap and the lateral width of the second airgap are substantially the same.

Example 10 includes the integrated circuit of any one of Examples 1-9, wherein the airgap extends along the second direction for an entire length of the gate structure in the second direction.

Example 11 includes the integrated circuit of any one of Examples 1-10, wherein the airgap extends along the second direction for at least 25 nm.

Example 12 includes the integrated circuit of any one of Examples 1-11, wherein the airgap extends in a third direction along an entire height of the gate structure.

Example 13 includes the integrated circuit of Example 12, wherein the airgap is also between the gate structure and the source or drain region.

Example 14 includes the integrated circuit of any one of Examples 1-13, further comprising a dielectric layer beneath the gate structure, wherein the dielectric layer extends across the airgap.

Example 15 is a printed circuit board comprising the integrated circuit of any one of Examples 1-14.

Example 16 is an electronic device that includes a chip package having one or more dies. At least one of the one or more dies includes a semiconductor region extending in a first direction from a first source or drain region to a second source or drain region, a gate structure extending in a second direction over the semiconductor region with the second direction being different from the first direction, a contact on a surface of the source or drain region, and an airgap between an upper portion of the gate structure and the contact and between a remaining portion of the gate structure and the source or drain region. The airgap has a lateral width along the first direction between the gate structure and the contact.

Example 17 includes the electronic device of Example 16, wherein the contact comprises tungsten, cobalt, ruthenium, or molybdenum.

Example 18 includes the electronic device of Example 16 or 17, wherein the gate structure comprises a gate dielectric and a gate electrode on the gate dielectric, and the at least one of the one or more dies further comprises a dielectric liner along outside edges of the contact.

Example 19 includes the electronic device of Example 18, wherein the gate dielectric comprises a high-k dielectric material and the dielectric liner comprises silicon and nitrogen.

Example 20 includes the electronic device of Example 18 or 19, wherein the airgap is directly between the gate dielectric of the gate structure and the dielectric liner.

Example 21 includes the electronic device of any one of Examples 18-20, wherein the gate dielectric is directly on the semiconductor region.

Example 22 includes the electronic device of any one of Examples 16-21, wherein the lateral width of the airgap is in the range of about 3 nm to about 20 nm.

Example 23 includes the electronic device of any one of Examples 16-22, wherein the semiconductor region is a first semiconductor region, the gate structure is a first gate structure, and the airgap is a first airgap. The at least one of the one or more dies further includes a second semiconductor device having a second semiconductor region extending in the first direction from the source or drain region and a second gate structure extending in the second direction over the second semiconductor region, and a second airgap between an upper portion of the second gate structure and the contact and between a remaining portion of the second gate structure and the source or drain region. The second airgap has a lateral width along the first direction.

Example 24 includes the electronic device of Example 23, wherein the lateral width of the first airgap and the lateral width of the second airgap are substantially the same.

Example 25 includes the electronic device of any one of Examples 16-24, wherein the airgap extends in a third direction along an entire height of the gate structure.

Example 26 includes the electronic device of any one of Examples 16-25, wherein the at least one of the one or more dies further comprises a dielectric layer beneath the gate structure. The dielectric layer extends across the airgap.

Example 27 includes the electronic device of any one of Examples 16-26, further comprising a printed circuit board, wherein the chip package is coupled to the printed circuit board.

Example 28 is a method of forming an integrated circuit. The method includes forming a fin comprising semiconductor material, the fin extending above a substrate and extending in a first direction; forming a dielectric layer adjacent to a subfin portion of the fin; forming a sacrificial gate and a sacrificial gate spacer on a sidewall of the sacrificial gate, the sacrificial gate extending over the semiconductor material in the second direction; forming a source or drain region at one end of the fin; forming a conductive contact on the source or drain region (e.g., and/or on sidewalls of the source or drain region, and/or extending within the source or drain region); removing the sacrificial gate and forming a gate structure on the dielectric layer in place of the sacrificial gate; removing the substrate from the backside of the integrated circuit, wherein the removing exposes a bottom surface of the dielectric layer; removing the dielectric layer from the backside of the integrated circuit such that at least a portion of the sacrificial gate spacer is exposed from the backside; and removing the sacrificial gate spacer from the backside of the integrated circuit to form an airgap between the gate structure and the contact.

Example 29 includes the method of Example 28, wherein the sacrificial gate spacer comprises aluminum and oxygen.

Example 30 includes the method of Example 28 or 29, wherein the sacrificial gate comprises polysilicon.

Example 31 includes the method of any one of Examples 28-30, wherein removing the sacrificial gate spacer comprises applying an ammonia gas to etch the sacrificial gate spacer.

Example 32 includes the method of any one of Examples 28-31, wherein forming the gate structure comprises forming a gate dielectric and a gate electrode on the gate dielectric.

Example 33 includes the method of any one of Examples 28-32, further including removing the subfin portion beneath the gate structure from the backside of the integrated circuit; and forming a backside dielectric layer beneath the gate structure, wherein the backside dielectric layer extends across the airgap.

Example 34 is an integrated circuit that includes a first semiconductor device having a first semiconductor region extending in a first direction from a first side of a source or drain region and a first gate structure extending in a second direction over the first semiconductor region, a second semiconductor device having a second semiconductor region extending in the first direction from a second side of the source or drain region opposite from the first side and a second gate structure extending in the second direction over the second semiconductor region, a contact on a top surface of the source or drain region, a first airgap between an upper portion of the first gate structure and the contact, and a second airgap between an upper portion of the second gate structure and the contact. The first airgap has a first lateral width along the first direction and the second airgap has a second lateral width along the first direction. The second lateral width is substantially the same as the first lateral width.

Example 35 includes the integrated circuit of Example 34, wherein the contact comprises tungsten, cobalt, ruthenium, or molybdenum.

Example 36 includes the integrated circuit of Example 34 or 35, wherein each of the first gate structure and second gate structure comprises a gate dielectric and a gate electrode on the gate dielectric, and the integrated circuit further comprises a dielectric liner along outside edges of the contact.

Example 37 includes the integrated circuit of Example 36, wherein the gate dielectric comprises a high-k dielectric material and the dielectric liner comprises silicon and nitrogen.

Example 38 includes the integrated circuit of Example 36 or 37, wherein the first airgap is directly between the gate dielectric of the first gate structure and the dielectric liner, and the second airgap is directly between the gate dielectric of the second gate structure and the dielectric liner.

Example 39 includes the integrated circuit of any one of Examples 36-38, wherein the gate dielectric of the first gate structure is directly on the first semiconductor region, and the gate dielectric of the second gate structure is directly on the second semiconductor region.

Example 40 includes the integrated circuit of any one of Examples 34-39, wherein each of the first lateral width and the second lateral width is in the range of about 3 nm to about 20 nm.

Example 41 includes the integrated circuit of any one of Examples 34-40, wherein both the first airgap and the second airgap extend in a third direction along an entire height of the first gate structure and second gate structure, respectively.

Example 42 includes the integrated circuit of Example 41, wherein the first airgap is also between the first gate structure and the source or drain region, and the second airgap is also between the second gate structure and the source or drain region.

Example 43 includes the integrated circuit of any one of Examples 34-42, further comprising a dielectric layer beneath the first gate structure and the second gate structure, wherein the dielectric layer extends across the first airgap and across the second airgap.

Example 44 is a printed circuit board comprising the integrated circuit of any one of Examples 34-43.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor device having a semiconductor region extending in a first direction from a source or drain region, and a gate structure extending in a second direction over the semiconductor region;
a contact on a surface of the source or drain region; and
an airgap between an upper portion of the gate structure and the contact, the airgap having a lateral width along the first direction between the upper portion of the gate structure and the contact.

2. The integrated circuit of claim 1, wherein the lateral width of the airgap is in the range about 3 nm to about 20 nm.

3. The integrated circuit of claim 1, wherein the semiconductor device is a first semiconductor device, the semiconductor region is a first semiconductor region, the gate structure is a first gate structure, and the airgap is a first airgap, the integrated circuit further comprising:
a second semiconductor device having a second semiconductor region extending in the first direction from the source or drain region, and a second gate structure extending in the second direction over the second semiconductor region; and
a second airgap between an upper portion of the second gate structure and the contact, the second airgap having a lateral width along the first direction between the upper portion of the second gate structure and the contact.

4. The integrated circuit of claim 3, wherein the lateral width of the first airgap and the lateral width of the second airgap are substantially the same.

5. The integrated circuit of claim 1, wherein the airgap extends along the second direction for an entire length of the gate structure in the second direction.

6. The integrated circuit of claim 1, wherein the airgap extends in a third direction along an entire height of the gate structure.

7. The integrated circuit of claim 6, wherein the airgap is also between the gate structure and the source or drain region.

8. The integrated circuit of claim 1, further comprising a dielectric layer beneath the gate structure, wherein the dielectric layer extends across the airgap.

9. A printed circuit board comprising the integrated circuit of claim 1.

10. An electronic device, comprising:
a chip package comprising one or more dies, at least one of the one or more dies comprising
a semiconductor region extending in a first direction from a first source or drain region to a second source or drain region;
a gate structure extending in a second direction over the semiconductor region, the second direction being different from the first direction;
a contact on a surface of the source or drain region; and
an airgap between an upper portion of the gate structure and the contact and between a remaining portion of the gate structure and the source or drain region, the airgap having a lateral width along the first direction between the gate structure and the contact.

11. The electronic device of claim 10, wherein the lateral width of the airgap is in the range of about 3 nm to about 20 nm.

12. The electronic device of claim 10, wherein the semiconductor region is a first semiconductor region, the gate structure is a first gate structure, and the airgap is a first airgap, the at least one of the one or more dies further comprising:
a second semiconductor region extending in the first direction from the source or drain region, and a second gate structure extending in the second direction over the second semiconductor region; and
a second airgap between an upper portion of the second gate structure and the contact and between a remaining portion of the second gate structure and the source or drain region, the second airgap having a lateral width along the first direction.

13. The electronic device of claim 12, wherein the lateral width of the first airgap and the lateral width of the second airgap are substantially the same.

14. The electronic device of claim 10, wherein the airgap extends in a third direction along an entire height of the gate structure.

15. An integrated circuit comprising:
a first semiconductor device having a first semiconductor region extending in a first direction from a first side of a source or drain region, and a first gate structure extending in a second direction over the first semiconductor region;
a second semiconductor device having a second semiconductor region extending in the first direction from a second side of the source or drain region opposite from the first side, and a second gate structure extending in the second direction over the second semiconductor region;
a contact on a top surface of the source or drain region;
a first airgap between an upper portion of the first gate structure and the contact, the first airgap having a first lateral width along the first direction; and
a second airgap between an upper portion of the second gate structure and the contact, the second airgap having a second lateral width along the first direction, wherein the second lateral width is substantially the same as the first lateral width.

16. The integrated circuit of claim 15, wherein the contact comprises tungsten, cobalt, ruthenium, or molybdenum.

17. The integrated circuit of claim 15, wherein each of the first lateral width and the second lateral width is in the range of about 3 nm to about 20 nm.

18. The integrated circuit of claim 15, wherein both the first airgap and the second airgap extend in a third direction along an entire height of the first gate structure and second gate structure, respectively.

19. The integrated circuit of claim 18, wherein the first airgap is also between the first gate structure and the source or drain region, and the second airgap is also between the second gate structure and the source or drain region.

20. The integrated circuit of claim 15, further comprising a dielectric layer beneath the first gate structure and the second gate structure, wherein the dielectric layer extends across the first airgap and across the second airgap.
